(19) United States
(12) Patent Application Publication
(10) Pub. No.: US 2007/0096171 A1
(43) Pub. Date: May 3, 2007

(54) Semiconductor laser device that has the effect of phonon-assisted light amplification and method for manufacturing the same

(76) Inventors: Ching-Fuh Lin, Taipei (TW); Chu-Ting Huang, Taipei (TW); Shu-Chia Hsu, Taipei (TW); Kung-An Lin, Taipei (TW); Eih-Zhe Liang, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/261,484

(22) Filed: Oct. 31, 2005

(51) Int. Cl. H01S 5/00; H01L 29/76; H01L 21/8234

(52) U.S. Cl. 257/288; 372/50.22; 438/197; 257/E33.052

(57) ABSTRACT

A semiconductor laser device that has the effect of phonon-assisted light amplification and a method for manufacturing the same are proposed. A conductive layer is formed on a semiconductor silicon substrate. A current flow is used to accomplish electro-luminescence of silicon. A silicon dioxide nanometer particle layer is sandwiched between the conductive layer and the semiconductor silicon substrate to form a MOS junction for carrier confinement. The phonon-assisted light emission mechanism can thus be strengthened to enhance the electro-luminescence efficiency of silicon so as to accomplish the lasing effect.

### BACKGROUND OF THE INVENTION

1. Field of the Invention

The present invention relates to a semiconductor laser device and, more particularly, to a semiconductor laser device that has the effect of phonon-assisted light amplification and a method for manufacturing the same.

2. Description of Related Art

Indirect bandgap materials are not used in any existent electro-luminescence semiconductor laser as media for light amplification. The reason is that structures capable of producing sufficient light amplification have not yet been developed from indirect bandgap materials like silicon. Because silicon ICs develop fast, in order to expand the applications of silicon in the field of electro-optics, the development of silicon lasers is much demanded.

Recently, much research has been devoted to the silicon material itself or the light emission or even light amplification phenomenon of silicon material, e.g., porous silicon, extrinsic doping, silicon dioxide ion implantation, erbium-doped silicon dioxide, SiGe or SiSn alloy, nanometer grain silicon, quantum confinement structure, coated light emission organic layer, grown GaN, and so on. The above or other techniques, however, cannot be easily integrated with the ULSI technology, causing much difficulty in commercialization. On the other hand, because the technique of using structures such as defect loops or MOS junctions to accomplish high-efficiency light emission of silicon is consistent with the ULSI technology, electronic devices can be easily integrated with the light source on the same silicon chip. Although the above structures can achieve an external light emission efficiency of 10⁻², no current-excited lasing phenomenon has ever been observed.

Photo-excited gain phenomenon of silicon material has been realized already, and photo gain phenomenon has been observed in silicon nanometer grains. DC-operated photo-excited silicon Raman lasers have currently been developed by the Intel. It is difficult for silicon materials to realize current-excited lasing phenomena. The reason is that Si is an indirect bandgap material having low electro-luminescence light emission efficiency. The light emission rate of direct bandgap materials is about 10⁹/s, the non-radiation rate thereof is about 10⁵/s. The non-radiation rate of silicon material is approximately equal to that of direct bandgap materials, but the radiation rate thereof is about 10⁴/s, only one tenth of the non-radiation rate. Therefore, how to increase the radiation rate and decrease the non-radiation rate of indirect bandgap materials like Si to achieve high-efficiency light emission and to further produce Si laser devices is a very important topic in this industry.

### SUMMARY OF THE INVENTION

An object of the present invention is to provide a semiconductor laser device that has the effect of phonon-assisted light amplification and a method for manufacturing the same, which produce laser light of silicon and enhance the light emission efficiency by that has the effect of phonon-assisted light amplification.

Another object of the present invention is to provide a semiconductor laser device that has the effect of phonon-assisted light amplification and a method for manufacturing the same, which conform to existent IC fabrication processes and thus facilitate commercialization.

Another object of the present invention is to provide a semiconductor laser device that has the effect of phonon-assisted light amplification and a method for manufacturing the same, whereby the manufactured semiconductor laser device has a simple structure, a small size, and an easy fabrication process. Therefore, the production cost can be reduced, and the market competitiveness can be enhanced.

To achieve the above objects, the present invention provides a method for manufacturing a semiconductor laser device that has the effect of phonon-assisted light amplification. The method comprises the steps of: providing a clean semiconductor silicon substrate; etching the semiconductor silicon substrate to remove a native oxide on the surface of the semiconductor silicon substrate; forming a silicon dioxide nanometer particle layer and a thin oxide on the semiconductor silicon substrate; and forming a conductive layer on the nanometer particle layer. The nanometer particle layer has a plurality of holes. The silicon dioxide nanometer particle layer is formed on the thin oxide, or the silicon dioxide nanometer particle layer is formed on the semiconductor silicon substrate and exposes in the atmosphere to form another thin oxide right on the semiconductor silicon substrate. Part of the surface of the semiconductor silicon substrate will be exposed out of the holes. The exposed surface of the semiconductor silicon substrate will contact the atmosphere to form the above thin oxide. An electrode layer can further be formed on the back face of the semiconductor silicon substrate to accomplish electro-luminescence of the semiconductor silicon substrate by means of current flow. Here, a MOS junction is utilized to enhance accumulation of carriers. Migration of metal atoms in the nanometer particle layer is utilized to form the MOS junction of nanometer structure so as to have the tunneling current phenomenon in nanometer range for current conduction. The light amplification efficiency can therefore be enhanced.

Besides, the present invention also provides a semiconductor laser device that has the effect of phonon-assisted light amplification, which comprises a semiconductor silicon substrate, a silicon dioxide nanometer particle layer, a thin oxide, a conductive layer, and an electrode layer. The silicon dioxide nanometer particle layer and the thin oxide are formed on the semiconductor silicon substrate. The silicon dioxide nanometer particle layer has a plurality of holes. The diameter of these holes is 0.5 nm to 1 μm. The silicon dioxide nanometer particle layer is on the thin oxide, or the thin oxide is exposed out of the holes of the silicon dioxide nanometer particle layer. The conductive layer is formed on top of the nanometer particle layer, and the electrode layer is formed on the back face of the semiconductor silicon substrate so that a voltage can be applied across the nanometer particle layer to drive atoms in the conductive layer to migrate to the oxide exposed out of the surface of the semiconductor silicon substrate. Carrier confinement in nanometer range can thus be achieved to enhance the electro-luminescence efficiency of the semiconductor laser device.

### BRIEF DESCRIPTION OF THE DRAWINGS

The various objects and advantages of the present invention will be more readily understood from the following detailed description when read in conjunction with the appended drawing, in which:

FIG. 1 is a flowchart of a method for manufacturing a semiconductor laser device using phonon-assisted light amplification technique of the present invention;

FIGS. 2A to 2E are cross-sectional views showing the steps of the method for manufacturing a semiconductor laser device of the present invention;

FIG. 3 is a voltage versus current diagram before and after migration of silver atoms of the semiconductor laser device of the present invention;

FIG. 4 is an optical power versus current diagram of the semiconductor laser device of the present invention;

FIG. 5 is a light emission spectrum diagram under different currents of the semiconductor laser diode of the present invention;

FIG. 6 is a more detailed light emission spectrum near the center of the spectrum shown in FIG. 5; and

FIG. 7 is a light emission spectrum diagram measured at two different times under the same current of the semiconductor laser diode of the present invention.

### DETAILED DESCRIPTION OF THE PREFERRED EMBODIMENTS

The present invention provides a semiconductor laser device that has the effect of phonon-assisted light amplification and a method for manufacturing the same, which makes use of the DC-operated phonon-assisted light amplification technique corresponding to silicon energy gap at room temperature. The phonon-assisted stimulated emission mechanism of silicon material is similar to the stimulated Raman scattering mechanism, both emitting photons and phonons. The stimulated Raman scattering, however, absorbs a high-energy photon to emit a lower-energy photon and phonon. The phonon-assisted stimulated emission emits photons and phonons through the recombination of electron-hole pair. Moreover, the phonons generated by the phonon-assisted light emission are at the band edge because of the momentum difference between electron and hole. The present invention utilizes nanometer particles to provide carrier confinement so that injected electrons and holes can easily form excitons at the junction of silicon and silicon dioxide, hence enhancing phonon-assisted light emission to produce light amplification. The idea of using nanometer structure to achieve carrier confinement can derive several kinds of designs of nanometer structure, and applies to all indirect bandgap materials including element and compound semiconductors such as Si, Ge, SiGe, SiC, GaP, and AlAs, and can further cover several kinds of wavelengths including communication bands, visible light, and UV light.

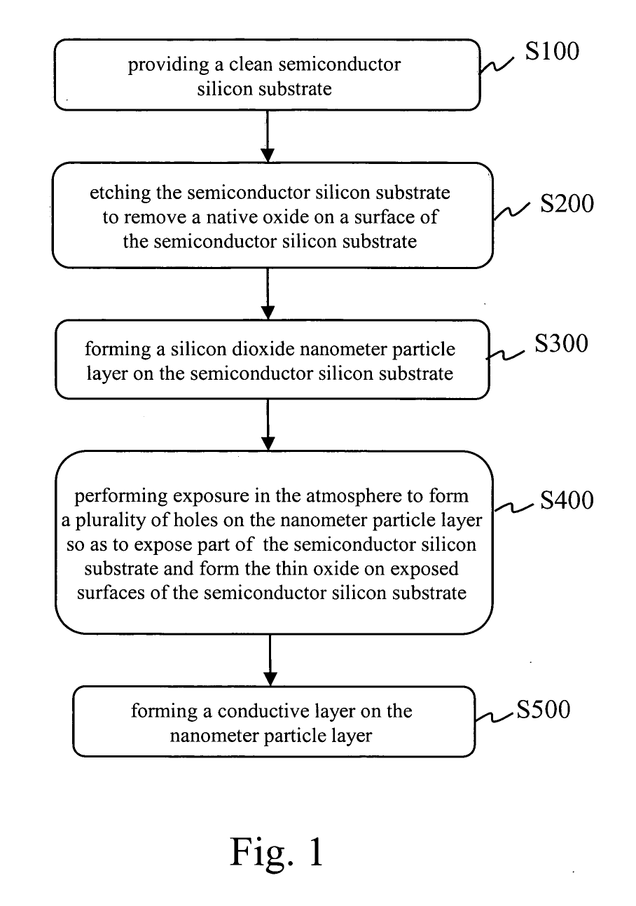

FIG. 1 is a flowchart of a method for manufacturing a semiconductor laser device using phonon-assisted light amplification technique of the present invention. First, a clean semiconductor silicon substrate is provided (Step S100). The semiconductor silicon substrate is then etched to remove the native oxide on the surface of the semiconductor silicon substrate (Step S200). Next, a silicon dioxide nanometer particle layer is formed on the semiconductor silicon substrate (Step S300). Subsequently, the sample is exposed in the atmosphere and a thin oxide is formed on the surface of the semiconductor silicon substrate because oxygen and moisture can reach the surface through the holes among the silicon dioxide nanometer particle (Step S400). Finally, a conductive layer is formed on the nanometer particle layer (Step S500). A semiconductor laser device is thus formed.

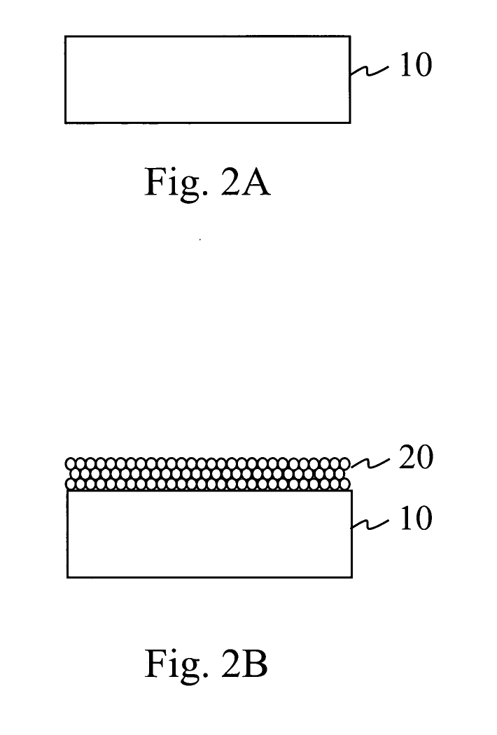

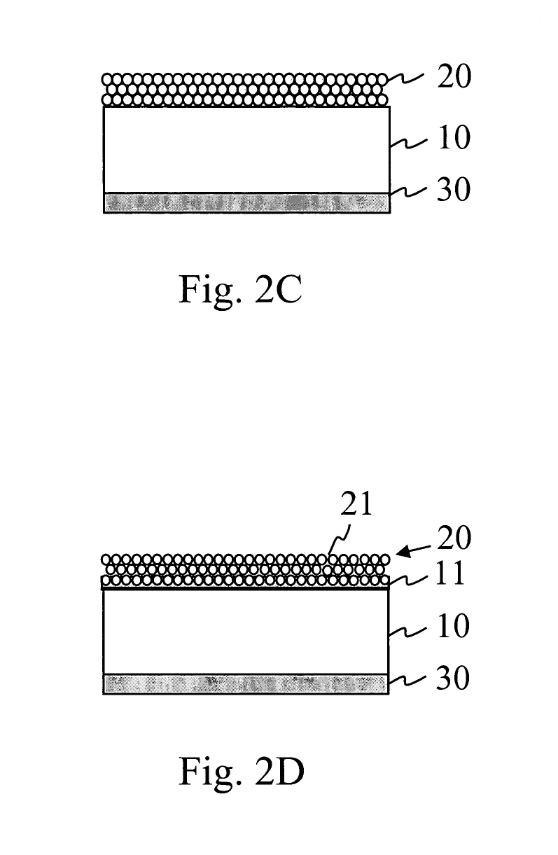

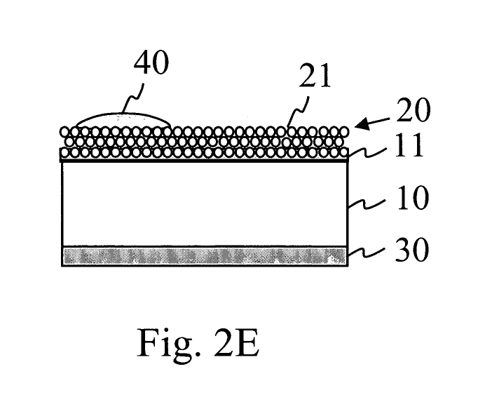

FIGS. 2A to 2E are cross-sectional views showing the steps of the method for manufacturing a semiconductor laser device of the present invention. First, as shown in FIG. 2A, a 2-inch n-type semiconductor silicon substrate 10 manufactured by the float zone method is used. The carrier lifetime is 500 μs to 1 ms. Acetone, methyl alcohol, and deionized water are separately used to clean the surface of the semiconductor silicon substrate 10. An oxide etchant is then used to remove the native oxide on the surface of the semiconductor silicon substrate 10.

Next, as shown in FIG. 2B, silicon dioxide nanometer particles are suspended in an isopropanol solvent to make a silicon dioxide nanometer particle suspension solution, which is then spin-coated on the surface of the cleaned semiconductor silicon substrate 10. Here, the diameter of the silicon dioxide nanometer particles is 8 to 12 nm. The silicon dioxide nanometer particles occupy about 25.5 wt % of the original solution, and the solvent is isopropanol or methyl alcohol. If water is used as the solvent, the silicon dioxide nanometer particles cannot be coated on the semiconductor silicon substrate. After spin-coating, a soft bake at 90° C. is preformed for 2 min to remove the solvent (isopropanol or methyl alcohol) so as to form a silicon dioxide nanometer particle layer 20 on the surface of the semiconductor silicon substrate 10.

As shown in FIG. 2C, a 200 nm conductive metal such as Al is evaporated at the back face of the semiconductor silicon substrate 10 to be used as an electrode layer 30, forming a conductive end of the semiconductor silicon substrate 10. The thickness of the electrode layer 30 is 100 nm to 500 nm.

Subsequently, as shown in FIG. 2D, because the exposure step has a significant influence to the performance of the manufactured device, the above device is placed in the atmosphere for 5 days to form several holes in the silicon dioxide nanometer particle layer 20. Oxygen and moisture can therefore touch the surface of the semiconductor silicon substrate 10 to form a thin oxide 11 of about 0.5 nm to 5 nm thick after a period of time.

Finally, as shown in FIG. 2E, silver paste is coated on the silicon dioxide nanometer particle layer 20 to be used as a conductive layer 40. The coated area is about 1 mm². The size of the sliced device is 4 mm². A gold wire is bonded to the conductive layer 40 and connected to a current source.

The manufactured semiconductor laser device that has the effect of phonon-assisted light amplification according to this embodiment of the present invention is a MOS junction diode having nanometer structures, as shown in FIG. 2E. The semiconductor laser device comprises a semiconductor silicon substrate 10, a silicon dioxide nanometer particle layer 20, an electrode layer 30, and a conductive layer 40. The thickness of the silicon dioxide nanometer particle layer is about 100 nm, and can be 0.5 to 1000 nm. The silicon dioxide nanometer particle layer 20 is disposed between the conductive layer 40 and the semiconductor silicon substrate 10 to have an insulation effect. The silicon dioxide nanometer particle layer 20 has several holes 21, which can be circular or bar-shaped, and of uniform or nonuniform sizes. The diameter of the holes can be 0.5 nm to 1 μm. Part of the surface of the semiconductor silicon substrate 10 is exposed out of the holes. The exposed surface of the semiconductor silicon substrate 10 has a thin oxide 11. The current can flow through the conductive layer 40. The material of the conductive layer 40 can be metal, doped semiconductor, or doped dielectric. Electro-luminescence of silicon is accomplished by means of current flow. There are two kinds of electro-luminescence: DC and non-DC. The back face of the semiconductor silicon substrate 10 is coated with Al to be used as the electrode layer 30. A voltage can therefore applied across the nanometer particle layer 20 to form a MOS junction for carrier accumulation. Through migration of metal atoms of the nanometer particle layer 20, metal nanometer wires are formed to form a MOS junction with nanometer structures. The phenomenon of tunneling current happens in nanometer range to conduct current, thereby enhancing the light emission efficiency of the semiconductor laser device. Besides, the thin oxide can first be formed on the semiconductor silicon substrate 10, and the silicon dioxide nanometer particle layer is then formed on the thin oxide to achieve the same effect.

After a voltage is applied across the semiconductor laser device, silver atoms of the conductive layer will be attracted by the electric field to move among nanometer particles so as to form silver nanometer wires and reach the thin oxide generated on the semiconductor silicon substrate that is placed in the atmosphere. The contacts will form a MOS tunneling current junction.

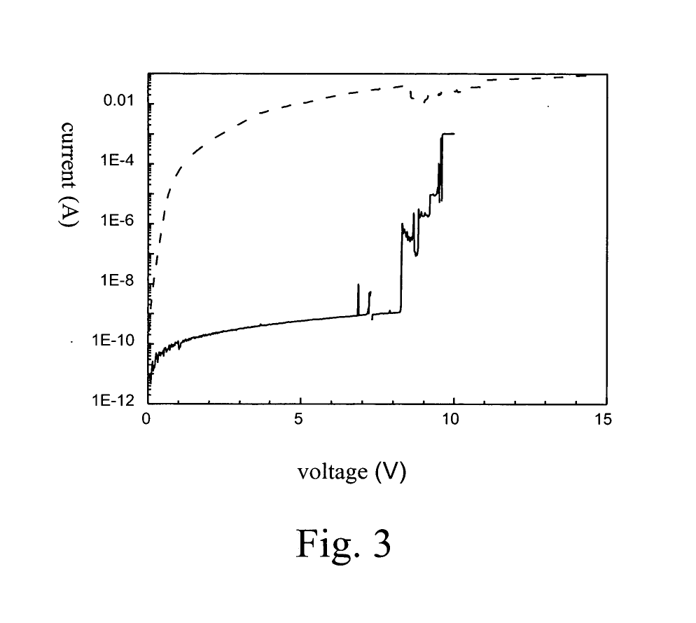

FIG. 3 is a voltage versus current diagram before and after migration of silver atoms of the semiconductor laser device of the present invention. Before the formation of silver nanometer wires, there is only a small current. When the device is biased above 7.5 V, a large current flows through, meaning the silver nanometer wires have formed a closed circuit. Hereafter, the current keeps stable, and the voltage-current relationship is the same as that of a common MOS tunnel diode.

Not all regions covered by silver paste have currents flowing through them. Currents only flow through the regions with silver nanometer wires. Other regions keep insulating. Silicon below the part of the thin oxide of the semiconductor silicon substrate touched by the silver nanometer wires will have a larger potential. Therefore, more energy band bending of the conduction band and the valence band in the semiconductor silicon substrate will be formed in this region. Majority carriers will thus accumulate in this region to achieve 3D confinement of majority carriers. Moreover, the tunneling current will bring minority carriers for this region, and other insulating regions will have no minority carriers, hence achieving confinement of minority carriers. The above two kinds of confinement cause overlap of the wave functions of electron and hole in space so that phonons can more easily interact with electron-hole pairs to accomplish the light emission effect and meet the requirement of conservation of momentum of the light emission mechanism of indirect bandgap materials. Therefore, this confinement region can provide light amplification through current excitation.

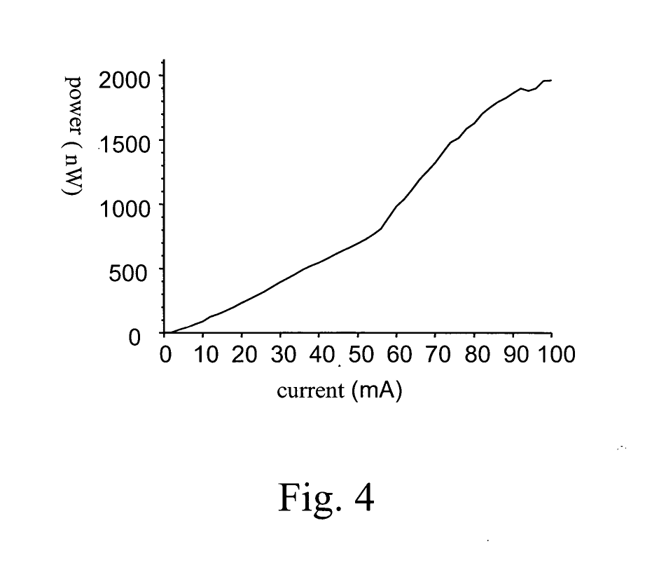

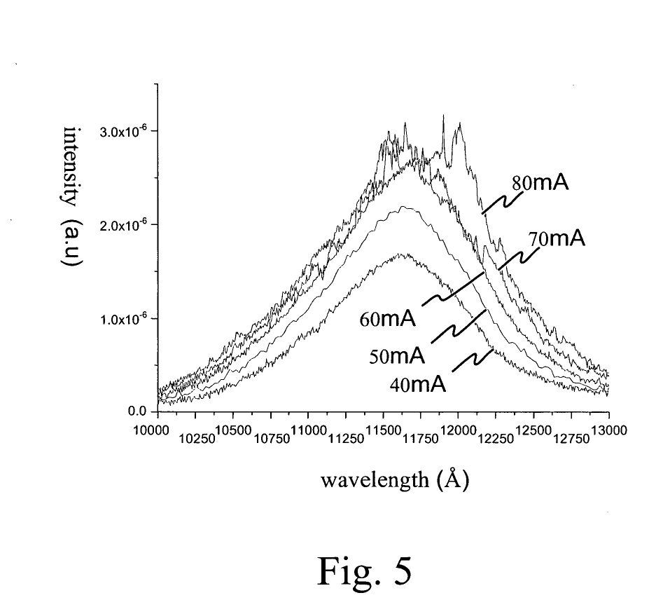

FIG. 4 is an optical power versus current diagram of the semiconductor laser device of the present invention. As can be seen from the figure, there is an obvious change of efficiency at 56 mA (corresponding to a current density of 7.13 A/cm²). FIG. 5 is a light emission spectrum diagram under different currents of the semiconductor laser diode of the present invention. The spectrum at the threshold current is a spontaneous emission spectrum, showing a smooth bell curve identical to photoluminescence and electro-luminescence spectra. When the current exceeds the threshold current, many peaks appear in the spectrum, meaning there is light amplification caused by stimulated emission in many frequency bands. All the above operations and measurements are under continous-wave (cw) situation and conducted at room temperature. The measurement had been repeated for several weeks. Moreover, the time period of each operation keeps for 5 to 10 hours.

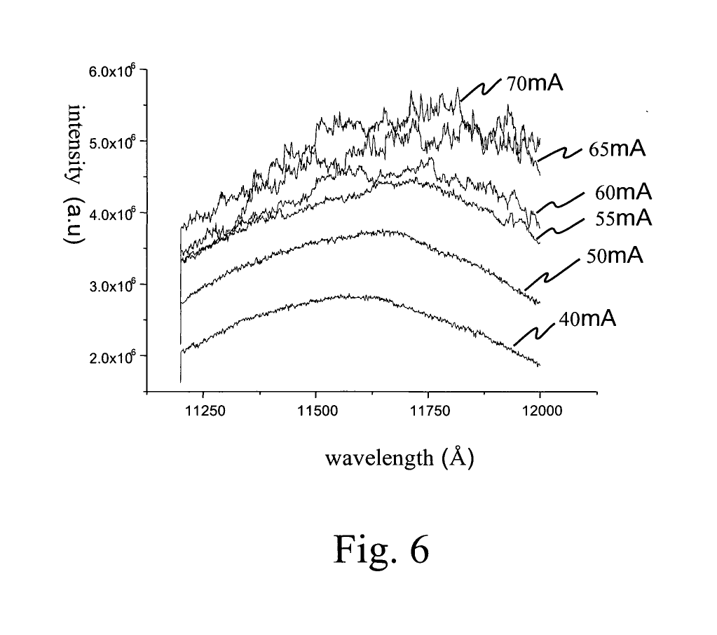

These peaks of light amplification primarily exist near the center of the spontaneous emission spectrum because of the larger optical gain at the center than at two ends of spectrum. FIG. 6 is a more detailed light emission spectrum near the center of the spectrum shown in FIG. 5. As can be more clearly seen in this figure, many peaks appear after the current exceeds the threshold current.

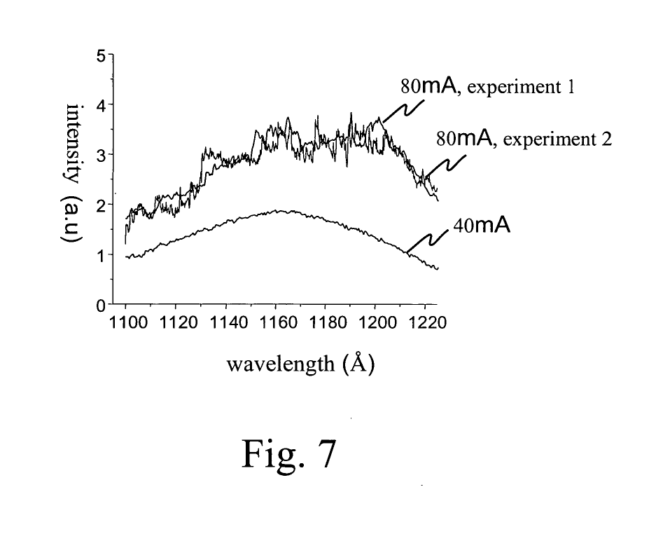

FIG. 7 is a light emission spectrum diagram measured at two different times under the same current (80 mA) of the semiconductor laser diode of the present invention. The reason is that there is no special design of resonance cavity in the semiconductor laser device. This phenomenon is similar to a random laser. Light travels a certain distance in the silicon material and goes back to the light emission region to gain light amplification. The reflection faces in the optical path can be silver paste conductive layer, space between particles in the nanometer particle layer, or silver nanometer wires. Light is reflected back to the regions for carrier confinement and light emission to obtain optical gain so as to achieve light amplification. Therefore, the amplification of light is accomplished by means of phonon-assisted stimulated emission. If the laser cavity is formed, then the emission spectrum will not be random. Instead, the lasing wavelength/spectrum can be controlled by the laser cavity.

The present invention has successfully utilized the current conduction structure of a nanometer structure MOS junction diode to produce laser lights at the infrared band corresponding to the energy gap of the silicon material.

In this nanometer structure MOS junction diode, the minority-carrier lifetime change with the injection current. It is estimated that the radiative-recombination rate is about ten times that of silicon substrate. The internal light emission efficiency can be higher than 60%. The reason why the light emission efficiency increases is that the nanometer particles provide confinement of carriers in space to more easily form excitons. Therefore, the phonon-assisted stimulated emission mechanism can be enhanced to accomplish the electro-luminescence phenomenon.

Besides, the present invention uses the coating of silicon dioxide nanometer particles to form an insulating layer that has no any damage to the silicon material. These nanometer particles won't deteriorate under the conventional semiconductor manufacturing processes, and conform to existent IC manufacturing processes, hence facilitating monolithic integration of electronic chip and light emission device and expanding the application range of silicon chip and silicon material. Moreover, the present invention has a simple structure, an easy manufacturing process, a low production cost, and a small volume, and can be integrated with the IC industry, hence being of large practical value. Furthermore, the SiO2 nanoparticles can be applied to other types of substrates for light emission at the bandgap of other semiconductors different from Si. Because the SiO2 nanoparticles cause no any change to the substrate underneath, this technique can be easily used for other types of semiconductors.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A method for manufacturing a semiconductor laser device that has the effect of phonon-assisted light amplification, comprising the steps of:
providing a clean semiconductor silicon substrate;
etching said semiconductor silicon substrate to remove a native oxide on a surface of said semiconductor silicon substrate;
forming a silicon dioxide nanometer particle layer and a thin oxide on said semiconductor silicon substrate, said nanometer particle layer having a plurality of holes; and
forming a conductive layer on said nanometer particle layer.

2. The method for manufacturing a semiconductor laser device that has the effect of phonon-assisted light amplification of claim 1, wherein said step of forming said silicon dioxide nanometer particle layer and said thin oxide on said semiconductor silicon substrate comprises the steps of:
forming said silicon dioxide nanometer particle layer on said semiconductor silicon substrate; and
performing exposure in the atmosphere to form said thin oxide on exposed surfaces of said semiconductor silicon substrate through plurality of holes on said nanometer particle layer.

3. The method for manufacturing a semiconductor laser device that has the effect of phonon-assisted light amplification of claim 1, wherein said step of forming said silicon dioxide nanometer particle layer and said thin oxide on said semiconductor silicon substrate comprises the steps of:
growing a thin oxide on said silicon on said semiconductor silicon substrate; and
forming said silicon dioxide nanometer particle layer on said thin oxide.

4. The method for manufacturing a semiconductor laser device that has the effect of phonon-assisted light amplification of claim 1, wherein said step of providing a semiconductor silicon substrate comprises a step of cleaning said semiconductor silicon substrate.

5. The method for manufacturing a semiconductor laser device that has the effect of phonon-assisted light amplification of claim 4, wherein acetone, methyl alcohol, or deionized water is used in said step of cleaning said semiconductor silicon substrate.

6. The method for manufacturing a semiconductor laser device that has the effect of phonon-assisted light amplification of claim 1, wherein said silicon dioxide nanometer particle layer is made by coating a silicon dioxide nanometer particle suspension solution on said semiconductor silicon substrate.

7. The method for manufacturing a semiconductor laser device that has the effect of phonon-assisted light amplification of claim 6, wherein silicon dioxide nanometer particles in said silicon dioxide nanometer particle suspension solution have a diameter of 8 to 12 nm.

8. The method for manufacturing a semiconductor laser device that has the effect of phonon-assisted light amplification of claim 6, wherein the solvent used in said silicon dioxide nanometer particle suspension solution is isopropanol or methyl alcohol.

9. The method for manufacturing a semiconductor laser device that has the effect of phonon-assisted light amplification of claim 8, further comprising a step of removing said solvent after forming said silicon dioxide nanometer particle layer.

10. The method for manufacturing a semiconductor laser device that has the effect of phonon-assisted light amplification of claim 9, wherein said step of removing said solvent is accomplished by baking said silicon dioxide nanometer particle suspension solution.

11. The method for manufacturing a semiconductor laser device that has the effect of phonon-assisted light amplification of claim 1, wherein the thickness of said nanometer particle layer is 0.5 to 1000 nm.

12. The method for manufacturing a semiconductor laser device that has the effect of phonon-assisted light amplification of claim 1, further comprising a step of forming an electrode layer on a back face of said semiconductor silicon substrate.

13. The method for manufacturing a semiconductor laser device that has the effect of phonon-assisted light amplification of claim 12, wherein said electrode layer is an aluminum layer.

14. The method for manufacturing a semiconductor laser device that has the effect of phonon-assisted light amplification of claim 12, wherein the thickness of said electrode layer is 100 to 500 nm.

15. The method for manufacturing a semiconductor laser device that has the effect of phonon-assisted light amplification of claim 1, wherein the thickness of said thin oxide is 0.5 to 5 nm.

16. The method for manufacturing a semiconductor laser device that has the effect of phonon-assisted light amplification of claim 1, wherein said conductive layer is formed by means of evaporation.

17. The method for manufacturing a semiconductor laser device that has the effect of phonon-assisted light amplification of claim 1, wherein said conductive layer is selected from the group that includes a metal layer, a doped semiconductor layer, and a doped dielectric layer.

18. The method for manufacturing a semiconductor laser device that has the effect of phonon-assisted light amplification of claim 17, wherein said metal conductive layer is a silver paste.

19. The method for manufacturing a semiconductor laser device that has the effect of phonon-assisted light amplification of claim 1, wherein the material of said semiconductor substrate is selected from the group of materials including Si, Ge, SiGe, SiC, GaP, and AlAs.

20. The method for manufacturing a semiconductor laser device that has the effect of phonon-assisted light amplification of claim 1, wherein the diameter of said holes is 0.5 nm to 1 μm.

21. A semiconductor laser device that has the effect of phonon-assisted light amplification comprising:
a semiconductor silicon substrate;
a silicon dioxide nanometer particle layer and a thin oxide formed on said semiconductor silicon substrate, said silicon dioxide nanometer particle layer having a plurality of holes;
a conductive layer formed on said nanometer particle layer; and
an electrode layer formed at a back face of said semiconductor silicon substrate.

22. The semiconductor laser device that has the effect of phonon-assisted light amplification of claim 21, wherein said thin oxide is formed by exposed to the environmental air or atmosphere out of said holes among said silicon dioxide nanometer particle layer.

23. The semiconductor laser device that has the effect of phonon-assisted light amplification of claim 21, wherein said silicon dioxide nanometer particle layer is formed on said thin oxide.

24. The semiconductor laser device that has the effect of phonon-assisted light amplification of claim 21, wherein the thickness of said nanometer particle layer is 0.5 to 1000 nm.

25. The semiconductor laser device that has the effect of phonon-assisted light amplification of claim 21, wherein said electrode layer is an aluminum layer.

26. The semiconductor laser device that has the effect of phonon-assisted light amplification of claim 21, wherein the thickness of said electrode layer is 100 to 500 nm.

27. The semiconductor laser device that has the effect of phonon-assisted light amplification of claim 21, wherein the thickness of said thin oxide is 0.5 to 5 nm.

28. The semiconductor laser device that has the effect of phonon-assisted light amplification of claim 21, wherein said conductive layer is formed by evaporation.

29. The semiconductor laser device that has the effect of phonon-assisted light amplification of claim 21, wherein said conductive layer is selected from the group that includes a metal layer, a doped semiconductor layer, and a doped dielectric layer.

30. The semiconductor laser device that has the effect of phonon-assisted light amplification of claim 29, wherein said metal conductive layer is a silver paste.

31. The semiconductor laser device that has the effect of phonon-assisted light amplification of claim 21, wherein the material of said semiconductor substrate is selected from the group of materials that include Si, Ge, SiGe, SiC, GaP, and AlAs.

32. The semiconductor laser device that has the effect of phonon-assisted light amplification of claim 21, wherein the diameter of said holes is 0.5 nm to 1 μm.
